(19) United States
(12) Patent Application Publication
(10) Pub. No.: US 2015/0072085 A1
(43) Pub. Date: Mar. 12, 2015

(54) TITANIUM BIS DIAZADIENYL PRECURSOR FOR VAPOR DEPOSITION OF TITANIUM OXIDE FILMS

(71) Applicant: L'Air Liquide, Société Anonyme pour l'Etude et l'Exploitation des Procédés Georges Claude, Paris (FR)

(72) Inventors: Clement LANSALOT-MATRAS, Seoul (KR); Jooho LEE, Seoul (KR)

(21) Appl. No.: 14/539,554

(22) Filed: Nov. 12, 2014

(51) Int. Cl. C23C 16/40; C23C 16/50

(52) U.S. Cl. CPC C23C 16/405; C23C 16/50
USPC 427/576; 427/255.36; 427/255.19

(57) ABSTRACT

Disclosed are methods of using the Ti(iPrDAD)₂ precursors to deposit Titanium oxide thin films on one or more substrates via vapor deposition processes.

### TECHNICAL FIELD

Disclosed are methods of depositing Titanium Oxide thin films on one or more substrates via vapor deposition processes using the Titanium bis-isopropylDiazadienyl precursor.

### BACKGROUND

Thin films of Titanium dioxide (TiO₂) have high refractive index, excellent transmittance in the visible and near-IR frequency, and high chemical stability. They have been shown to be useful as anti-reflection coating, sensors, and photocatalysts. The TiO₂ thin film is also a promising material for the development of microelectronics including as an alternative to ZrO₂ in the High-K dielectric of Dynamic Random Access Memory (DRAM), due to its high dielectric constant. Moreover, titanium oxide is a constituent of important multicomponent oxides such as BaTiO₃ and SrTiO₃, which are well known to be ferroelectrics. Recently, resistive switching in TiO₂ based metal-insulator-metal (MIM) structures attracted considerable interest. Alternatively titanium oxide can be used to dope the SiO₂ hard mask layer improving then the selectivity during the etching steps in the fabrication of the CMOS devices (US20120164846)

According to International Technology Roadmap for Semiconductors, for sub-22 nm node, requirements for the equivalent oxide thickness (EOT)<0.5 nm and leakage current density <1/10⁻⁷ A/cm² at 0.8 V are difficult to match. For the super High-K DRAM capacitor, the TiO₂ thin films were grown by ALD on a Ru bottom electrode using titanium isopropoxide (Ti(OCH(CH₃)₂)₄, TTIP), as a precursor and H₂O vapor and O₃ as oxidants. The film showed dielectric constant up to 100. (Applied physics Letters, 2004, 85, 4112-4114). Remarkable reduction of the leakage (below 10⁻⁷) current density was achieved by Al-doped TiO₂. Al-doping was performed by inserting Al₂O₃ cycle in 60, 90 and 90 TiO₂ cycles. Trimethylaluminium(Al(CH₃)₃, TMA) and TTIP were used as precursors for Al₂O₃ and TiO₂ deposition. (Advanced Materials, 2008, 20, 1429-1435.) Furthermore, Ti-based oxide such as SrTiO₃ and BaSrTiO₃ were identified as possible dielectric materials for DRAM capacitor for beyond 20 nm generation.

In the research of resistive random access memory, the resistive switching behavior of atomic-layer-deposited TiO₂ thin films (rutile structure), which were grown by ALD using Ti(OC₃H₇)₄ and O₃ as precursor and oxidant, respectively, at a wafer temperature of 250° C., was observed. Removing some of the oxygen ions from the rutile structure and arranging the oxygen vacancies on a specific crystallographic plane, which show distinctive conducting semiconductor or metallic characteristics. (Nat. Nanotechnol. 2010, 5, 148)

Vertically aligned TiO₂ nanotube arrays for H₂ gas sensor were fabricated by using atomic layer deposition combined with anodic aluminum oxide template. Morphology and crystalline structure of the TiO₂ nanotubes were characterized, and gas sensing properties at low temperatures (<200° C.) were investigated. The sensor showed a very short response time (<1 s) and a high selectivity for H₂ gas against several reducing gases including NH₃, CO, and C₂H₅OH. (Sensors and Actuators B, 2011, 160, 1494-1498)

For the dye-sensitized solar cells (DSSCs), plasmonic silver nanoparticles have unique properties that allow themselves to unusual optical applications, potentially including use as absorption amplifiers in dye-sensitized solar cells (DSSCs). However, these particles are easily damaged under oxidizing conditions. To avoid damage from oxidizing, TiO₂ using TTIP is coated by ALD. (Adv. Mater. 2010, 22, 2329-2332).

In the process of forming a CMOS device the space-defined double patterning (SDDP) is still the most promising method to create narrow pitches beyond limitations of conventional lithography such as light source wavelength and high index immersion fluid. Generally, SDDP needs one conformal spacer film and hardmask template wherein the conformal spacer film is deposited on the template normally having convex patterns. A silicon oxide layer is commonly used as a conformal spacer, and a hardmask template is typically constituted by photoresist (PR) or amorphous carbon (a-C) prepared by a spin-on or CVD process. In SDDP process flow, it is required for a spacer film to be etch-selective relative to a base film. It was found that the SixTi(1-x)Oy (TiSiO₄ for instance) hardmask material had a higher mechanical strength and higher chemical resistance (low dry etch rate) than that of a conventional SiO hardmask presenting thus much better selectivity during the etching steps (US20120164846). Typically the TiSiO₄ are prepared at low temperature down to 50° C. by PEALD by alternating subcycles of Titanium pulse using either TIPP or TDMAT, with Silicon pulse.

Aside from the above mentioned titanium precursors, some diazabutadiene based molecules have been developed. Diazabutadiene (DAD) ligands are α-diimine ligands that may be used under different oxidation states. The DAD ligand may be selected from one of three oxidation state forms, with each form determining the bonding mode between the center element (M) and the DAD ligands. As used herein, three different oxidation states of the ligand are described as i) neutral, ii) mono-anionic, and iii) dianionic. One of ordinary skill in the art will recognize that the location of the double bonds in the diazabutadiene ligand changes based upon the oxidation state of the ligand, as shown below:

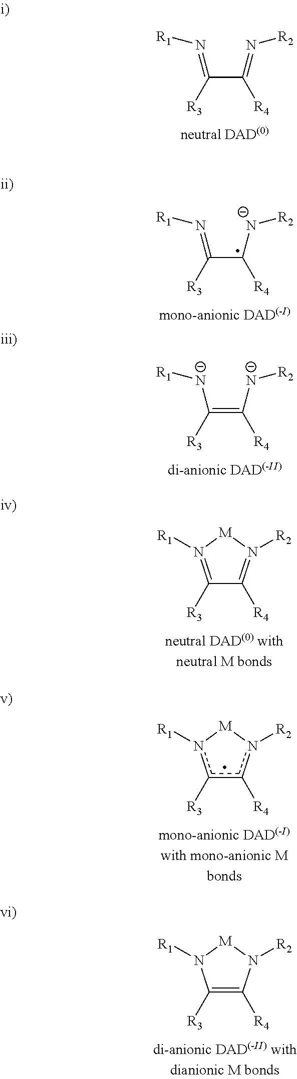

In Inorg. Chim. Acta, 177, 1990, P191-197, Heindirk Tom Dieck described for the first time the synthesis of Titanium bis-diazadienyl (Ti(iPrDAD)₂ & Ti(tBuDAD)₂) from the reaction of the bis lithiated diazadiene ligand with titanium tetrachloride (TiCl₄). Author mentioned that the volatile homoleptic DAD complexes can in principle be the source of Titanium nitride (TiN) or metal under appropriate CVD. However no evidence or experimental details were described.

In Journal de Physique IV, Colloque C3, supplement au Journal de Physique 11, Volume 3, 1993, the solid Ti(tBuDAD)₂ precursor was used in a CVD process with NH₃ co-reactant at temperatures higher than 400° C. targeting the Titanium nitride phase. However the growth rates of TIN deposition from Ti(t-BuDAD)₂/NH₃ only became noticeable at temperatures above 500° C. Low deposition rate and poor quality of the films were observed (carbon and oxygen contamination) showing that Ti(t-BuDAD)₂ is not an appropriate precursor for the TiN CVD process.

There is still a need for a sufficiently volatile and thermally stable titanium precursor allowing the deposition of pure titanium oxide thin films by Atomic Layer

Deposition (ALD) with high growth rate. As the Ti(iPrDAD)₂ precursor doesn't contain any Oxygen in its structure we have good reason to believe that providing an oxidizing gas as a co-reactant during the ALD process will allow to produce pure Titanium oxide thin films.

### SUMMARY

Disclosed are processes for the deposition of Titanium oxide films on one or more substrates using Titanium bis isopropylDiazabutadienyl (Ti(iPrDAD)₂). At least the Ti(iPrDAD)₂ precursor is introduced into a reactor having at least one substrate disposed therein. At least part of the Ti(iPrDAD)₂ precursor is deposited onto the at least one substrate, and at least part of an oxidizing reactant is introduced into a reactor to form the titanium oxide film.

The disclosed processes may further include one or more of the following aspects:

the Ti(iPrDAD)₂ precursor is Titanium bis isopropylDiazadienyl and has the formula (A)

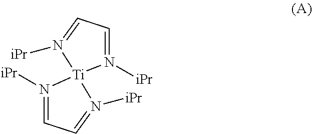

introducing at least one oxidizing reactant into the reactor;

the oxidizing reactant being plasma-treated;

the oxidizing reactant being remote plasma-treated;

the oxidizing reactant not being plasma-treated;

the oxidizing reactant being selected from the group consisting of: O₂, O₃, H₂O, H₂O₂, NO, N₂O, NO₂, oxygen radicals thereof, and mixtures thereof;

the oxidizing reactant being H₂O;

the oxidizing reactant being O₂;

the oxidizing reactant being plasma treated O₂;

the oxidizing reactant being O₃;

the Ti(iPrDAD)₂ precursor and the oxidizing reactant being introduced into the reactor simultaneously;

the reactor being configured for chemical vapor deposition;

the reactor being configured for plasma enhanced chemical vapor deposition;

the Ti(iPrDAD)₂ precursor and the oxidizing reactant being introduced into the chamber sequentially;

the reactor being configured for atomic layer deposition;

the reactor being configured for plasma enhanced atomic layer deposition;

the reactor being configured for spatial atomic layer deposition;

the titanium oxide film being a pure titanium oxide thin film;

the titanium oxide film having the formula TiₙOₘ, wherein and each of n and m is an integer which inclusively range from 1 to 6;

the titanium oxide film being TiO₂;

the substrate being silicon oxide (SiO₂).

### NOTATION AND NOMENCLATURE

Certain abbreviations, symbols, and terms are used throughout the following description and claims, and include:

As used herein, the indefinite article “a” or “an” means one or more.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “alkyl group” refers to saturated functional groups containing exclusively carbon and hydrogen atoms. Further, the term “alkyl group” refers to linear, branched, or cyclic alkyl group except for phenyl, cyclohexyl, pyrrole, pyrazoles. Examples of linear alkyl groups include without limitation, methyl groups, ethyl groups, propyl groups, butyl groups, etc.

Examples of branched alkyls groups include without limitation, i-propyl, t-butyl. Examples of cyclic alkyl groups include without limitation, cyclopropyl groups, cyclopentyl groups, etc.

As used herein, the abbreviation, “Me,” refers to a methyl group; the abbreviation, “Et,” refers to an ethyl group; the abbreviation, “Pr,” refers to a propyl group; the abbreviation, “iPr,” refers to an isopropyl group; the abbreviation “Bu” refers to butyl; the abbreviation “tBu” refers to tert-butyl; the abbreviation “sBu” refers to sec-butyl; the abbreviation “Cp” refers to cyclopentadienyl; the abbreviation “Cp*” refers to pentamethylcyclopentadienyl; the abbreviation “op” refers to (open)pentadienyl.

The standard abbreviations of the elements from the periodic table of elements are used herein. It should be understood that elements may be referred to by these abbreviations (e.g., Mn refers to manganese, Si refers to silicon, C refers to carbon, etc.).

### BRIEF DESCRIPTION OF THE FIGURES

For a further understanding of the nature and objects of the present invention, reference should be made to the following detailed description, taken in conjunction with the accompanying figure wherein:

FIG. 1 is a ThermoGravimetric Analysis (TGA)/Differential Thermal Analysis (DTA) graph demonstrating the percentage of weight loss (TGA) or the differential temperature (DTA) with increasing temperature of Ti(iPrDAD)₂;

FIG. 2 is a graph showing the growth rate of TiO₂ thin film using Ti(iPrDAD)₂ and H₂O as co-reactant as function of the source introduction time between 200 and 250° C.; and

FIG. 3 is a graph showing the dependence of TiO₂ thin films thickness on the number of deposition cycle.

### DESCRIPTION OF PREFERRED EMBODIMENTS

Disclosed are processes for the deposition of Titanium oxide films on one or more substrates using Titanium bis isopropylDiazabutadienyl (Ti(iPrDAD)₂). At least the Ti(iPrDAD)₂ precursor is introduced into a reactor having at least one substrate disposed therein. At least part of the Ti(iPrDAD)₂ precursor is deposited onto the at least one substrate, and at least part of an oxidizing reactant is introduced into a reactor to form the Titanium oxide film.

The Ti(iPrDAD)₂ precursor has the formula (A):

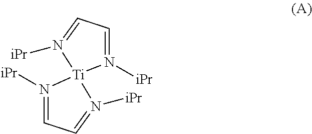

The disclosed Ti(iPrDAD)₂ compound may be synthesized according to the method described in Heindirk tom Dieck, Inorg. Chim. Acta, 177, 1990, P191-197 by reacting the bis lithiated isopropyldiazadiene with titanium tetrachloride in THF and hexane at low temperature.

The method may be useful in the manufacture of semiconductor, photovoltaic, LCD-TFT, or flat panel type devices. The disclosed Ti(iPrDAD)₂ compounds may be used to deposit thin Titanium oxide thin films using any deposition methods known to those of skill in the art. Examples of suitable deposition methods include without limitation, conventional chemical vapor deposition (CVD), atomic layer deposition (ALD), or other types of depositions that are related to vapor coating such as a plasma enhanced CVD (PECVD), plasma enhanced ALD (PEALD), pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), spatial ALD, hot-wire ALD (HWALD), radicals incorporated deposition, and super critical fluid deposition or combinations thereof. The deposition method is preferably ALD, PE-ALD, or spatial ALD in order to provide suitable step coverage and film thickness control.

The disclosed Ti(iPrDAD)₂ precursor may be supplied either in a neat form or in a blend with a suitable solvent, such as ethyl benzene, xylene, mesitylene, decane, dodecane. The disclosed compounds may be present in varying concentrations in the solvent.

The neat or blended Ti(iPrDAD)₂ compounds is introduced into a reactor in vapor form by conventional means, such as tubing and/or flow meters. The compound in vapor form may be produced by vaporizing the neat or blended compound solution through a conventional vaporization step such as direct vaporization, distillation, or by bubbling. The neat or blended compound may be fed in liquid state to a vaporizer where it is vaporized before it is introduced into the reactor. Alternatively, the neat or blended compound may be vaporized by passing a carrier gas into a container containing the compound or by bubbling the carrier gas into the compound. The carrier gas may include, but is not limited to, Ar, He, N₂, and mixtures thereof. Bubbling with a carrier gas may also remove any dissolved oxygen present in the neat or blended compound solution. The carrier gas and compound are then introduced into the reactor as a vapor.

If necessary, the container of disclosed compound may be heated to a temperature that permits the compound to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of compound vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor, or other types of deposition systems under conditions suitable to cause the compounds to react and form the layers.

Generally, the reactor contains one or more substrates onto which the thin films will be deposited. The substrates may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. The substrate may also have one or more layers of differing materials already deposited upon it from a previous manufacturing step. For example, a TiO₂ film may be deposited onto a Si or SiO₂ substrate.

The temperature and the pressure within the reactor are held at conditions suitable for ALD or CVD depositions. In other words, after introduction of the vaporized compound into the chamber, conditions within the chamber are such that at least part of the vaporized compound is deposited onto the substrate to form a titanium oxide film. For instance, the pressure in the reactor may be held between about 1 Pa and about 10⁵ Pa, more preferably between about 25 Pa and about 10³ Pa, as required per the deposition parameters. Likewise, the temperature in the reactor may be held between about 100° C. and about 400° C., preferably between about 150° C. and about 250° C. One of ordinary skill in the art will recognize that “at least part of the vaporized compound is deposited” means that some or all of the compound reacts with or adheres to the substrate.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 50° C. to approximately 400° C. When a plasma deposition process is utilized, the deposition temperature may range from approximately 50° C. to approximately 200° C. Alternatively, when a thermal process is performed, the deposition temperature may range from approximately 200° C. to approximately 400° C.

In addition to the disclosed compound, a reactant is also introduced into the reactor. The reactant is an oxidizing gas such as one of O₂, O₃, H₂O, H₂O₂, NO, N₂O, NO₂, oxygen containing radicals such as O— or OH—, NO, NO₂, carboxylic acids, formic acid, acetic acid, propionic acid, and mixtures thereof. Preferably, the oxidizing gas is selected from the group consisting of O₂, O₃, H₂O, H₂O₂, oxygen containing radicals thereof such as O— or OH—, and mixtures thereof.

The reactant may be treated by a plasma, in order to decompose the reactant into its radical form. For instance, the plasma may be generated with a power ranging from about 50 W to about 500 W, preferably from about 100 W to about 200 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The reactant may be introduced and held in the reaction chamber prior to plasma processing.

Alternatively, the plasma processing may occur simultaneously with the introduction of the reactant. In-situ plasma is typically a 13.56 MHz RF inductively coupled plasma that is generated between the showerhead and the substrate holder. The substrate or the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the reactant using in-situ plasma is typically less than achieved using a remote plasma source for the same power input and is therefore not as efficient in reactant disassociation as a remote plasma system, which may be beneficial for the deposition of Titanium-containing films on substrates easily damaged by plasma.

Alternatively, the plasma-treated reactant may be produced outside of the reaction chamber. The MKS Instruments' ASTRONi® reactive gas generator may be used to treat the reactant prior to passage into the reaction chamber. Operated at 2.45 GHz, 7 kW plasma power, and a pressure ranging from approximately 3 Torr to approximately 10 Torr, the reactant O₂ may be decomposed into two O radicals. Preferably, the remote plasma may be generated with a power ranging from about 1 kW to about 10 kW, more preferably from about 2.5 kW to about 7.5 kW.

The vapor deposition conditions within the chamber allow the disclosed compound and the reactant to react and form a Titanium oxide film on the substrate. In some embodiments, Applicants believe that plasma-treating the reactant may provide the reactant with the energy needed to react with the disclosed compound.

Depending on what type of film is desired to be deposited, an additional precursor compound may be introduced into the reactor. The precursor may be used to provide additional elements to the Titanium oxide film. The additional elements may include without limitation ruthenium, strontium, barium, calcium, magnesium, bismuth, zirconium, hafnium, lead, vanadium, niobium, tantalum, aluminum, lanthanum, or mixtures of these. When an additional precursor compound is utilized, the resultant film deposited on the substrate may contain Titanium oxide in combination with at least one additional element.

Ti(iPrDAD)₂ and the oxidizing gas may be introduced into the reactor either simultaneously (chemical vapor deposition), sequentially (atomic layer deposition) or different combinations thereof. The reactor may be purged with an inert gas between the introduction of the compound and the introduction of the oxidizing gas. Alternatively, the oxidizing gas and Ti(iPrDAD)₂ may be mixed together to form a oxidizing gas/Ti(iPrDAD)₂ mixture, and then introduced into the reactor in mixture form. Another example is to introduce the oxidizing gas continuously and to introduce Ti(iPrDAD)₂ by pulse (pulsed chemical vapor deposition).

The vaporized compound and the oxidizing gas may be pulsed sequentially or simultaneously (e.g. pulsed CVD) into the reactor. Each pulse of compound may last for a time period ranging from about 0.01 seconds to about 10 seconds, alternatively from about 0.3 seconds to about 3 seconds, alternatively from about 0.5 seconds to about 2 seconds. In another embodiment, the oxidant may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds. In another alternative, Ti(iPrDAD)₂ and one or more oxidizing gas may be simultaneously sprayed from a shower head under which a susceptor holding several wafers is spun (spatial ALD).

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD type process, the vapor phase of Ti(iPrDAD)₂ and an oxidizing gas are simultaneously introduced into the reactor. The two react to form the titanium oxide thin film. When the reactant in this exemplary CVD process is treated with a plasma, the exemplary CVD process becomes an exemplary PECVD process. The reactant may be treated with plasma prior or subsequent to introduction into the chamber.

In one non-limiting exemplary ALD type process, the vapor phase of Ti(iPrDAD)₂ is introduced into the reactor, where it is contacted with a suitable substrate. Excess Ti(iPrDAD)₂ may then be removed from the reactor by purging and/or evacuating the reactor. A desired gas (for example, O₃) is introduced into the reactor where it reacts with the absorbed Ti(iPrDAD)₂ in a self-limiting manner to form a Titanium oxide film. Any excess oxidizing gas is removed from the reactor by purging and/or evacuating the reactor. These two steps may be repeated until the Titanium oxide film obtains a desired thickness.

The resulting titanium oxide may be used in DRAM capacitors or for doping silicon oxide hard mask layers.

Alternatively, if the desired film contains Titanium and a second element, the two-step process above may be followed by introduction of the vapor of an additional precursor compound into the reactor. After introduction into the reactor, the additional precursor compound is contacted with the substrate. Any excess precursor compound is removed from the reactor by purging and/or evacuating the reactor. Once again, a desired gas may be introduced into the reactor to react with the precursor compound. Excess gas is removed from the reactor by purging and/or evacuating the reactor. If a desired film thickness has been achieved, the process may be terminated. However, if a thicker film is desired, the entire four-step process may be repeated. By alternating the provision of the Ti(iPrDAD)₂, additional precursor compound, and oxidizing gas, a film of desired composition and thickness can be deposited.

When the reactant in this exemplary ALD process is treated with a plasma, the exemplary ALD process becomes an exemplary PEALD process. The reactant may be treated with plasma prior or subsequent to introduction into the chamber.

The Titanium oxide thin films resulting from the processes discussed above may include a pure Titanium oxide of formula TiₙOₘ wherein m and n are integers which inclusively range from 1 to 6. One of ordinary skill in the art will recognize that by judicial selection of the appropriate disclosed compound, optional precursor compounds, and reactant species, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skills in the art recognize the systems and methods utilized to perform these additional processing steps. For example, the titanium oxide film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 400° C. for 3600 seconds under a H-containing atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Titanium oxide film. This in turn tends to improve the resistivity of the film.

In another alternative, Ti(iPrDAD)₂ may be used as doping or implantation agents. Part of the disclosed Ti(iPrDAD)₂ may be deposited on top of the film to be doped, such as a silicon oxide (SiO₂) film, an indium oxide (In₂O₃) film, a vanadium dioxide (VO₂) film, a copper oxide film, or a tin dioxide (SnO₂) film. The titanium oxide then diffuses into the film during an annealing step to form the titanium oxide-doped films. Alternatively, high energy ion implantation using a variable energy radio frequency quadrupole implanter may be used to dope the titanium of the disclosed compounds into a film. The implantation method of which is incorporated herein by reference in its entirety. In another alternative, plasma doping, pulsed plasma doping or plasma immersion ion implantation may be performed using the disclosed Ti(iPrDAD)₂.

### EXAMPLES

The following examples illustrate experiments performed in conjunction with the disclosure herein. The examples are not intended to be all inclusive and are not intended to limit the scope of disclosure described herein.

### Example 1

### Thermo Gravimetric Analysis (TGA) of Ti(iPrDAD)₂

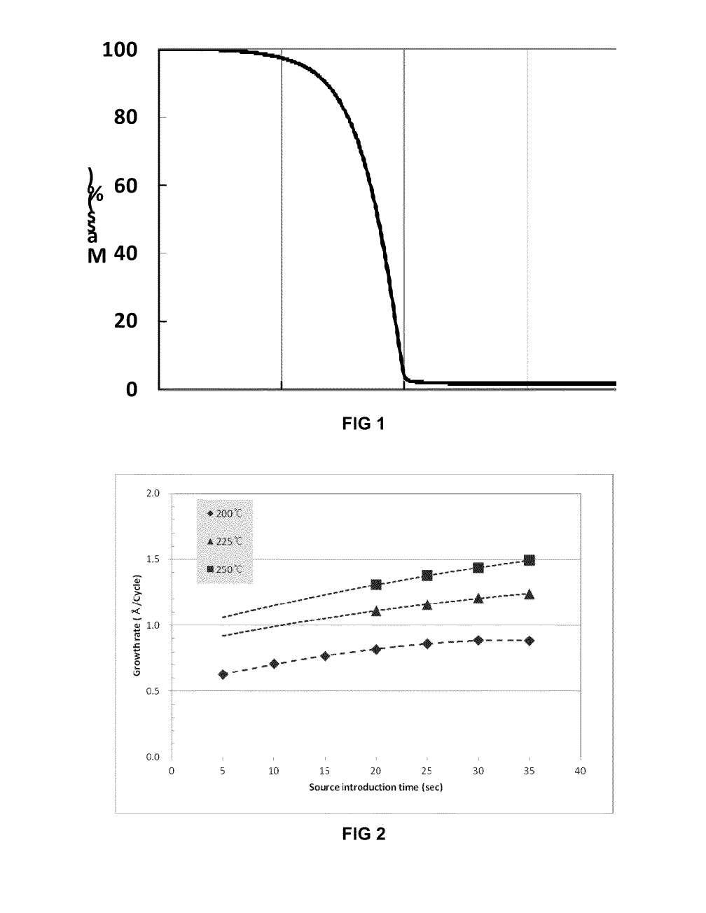

TGA was measured at a temperature rising rate of 10° C./min in an atmosphere which flows nitrogen at 200 mL/min. The result is depicted in FIG. 1 is a TGA graph demonstrating the percentage of weight loss with temperature change.

### Example 2

### ALD of Ti(iPrDAD)₂

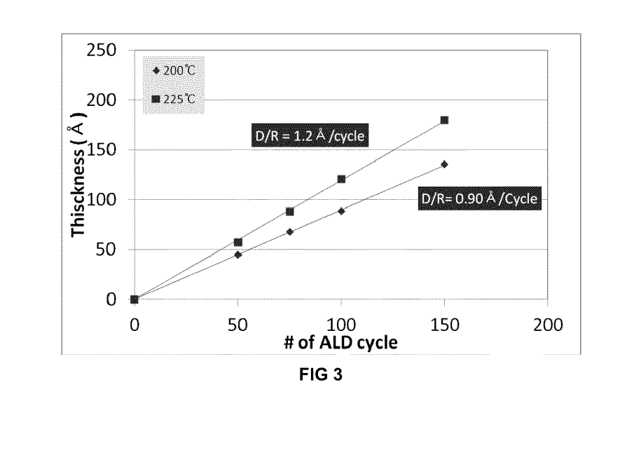

ALD tests were be performed using Ti(iPrDAD)₂ which was be placed in a vessel heated up to 110° C. and H₂O as Co-oxidizing reactant. Typical ALD conditions were used with a reactor pressure fixed at ˜0.5 Torr. ALD behavior with complete surface saturation and reaction will be assessed in a temperature window of 200-225° C. on pure silicon wafers. The growth rate in ALD window were in the range 0.9-1.2 Å/cycle. FIG. 2 shows growth the growth rates of TiO₂ thin films using Ti(iPrDAD)₂/H₃O as a function of the source introduction time between 200-250° C. FIG. 3 shows the dependence of TiO₂ thin films thickness as a function of the number of deposition cycle.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

We claim:

1. A process for the deposition of a titanium oxide thin film on a substrate, comprising the steps of:
introducing the vapors of the Ti(iPrDAD)₂ precursor into a reactor having a substrate disposed therein
depositing at least part of the Ti(iPrDAD)₂ precursor onto the substrate.
and introducing an oxidizing reactant to form the Titanium oxide thin film.

2. The process of claim 1 wherein Ti(iPrDAD)₂ precursor is Titanium bis isopropylDiazadienyl and has the formula (A):

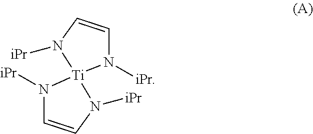

3. The process of claim 1, wherein the oxidizing reactant is selected from the group consisting of: O₂, O₃, H₂O, H₂O₂ NO, N₂O, NO₂, oxygen radicals thereof, and mixtures thereof.

4. The process of claim 1, wherein the Ti(iPrDAD)₂ precursor and the oxidizing reactant are introduced into the reactor simultaneously and the reactor is configured for chemical vapor deposition.

5. The process of claim 1, wherein the Ti(iPrDAD)₂ precursor and the oxidizing reactant are introduced into the chamber sequentially and the reactor is configured for atomic layer deposition.

6. The process of claim 1, wherein the substrate is silicon oxide (SiO₂).

7. The process of claim 1, wherein the process is plasma enhanced.
